(19) United States
(12) Patent Application Publication
(10) Pub. No.: US 2012/0105088 A1
(43) Pub. Date: May 3, 2012

(54) APPARATUS AND METHOD FOR TESTING BACK-CONTACT SOLAR CELLS

(75) Inventor: BRIAN J. MURPHY, Albuquerque, NM (US)

(73) Assignee: APPLIED MATERIALS, INC., Santa Clara, CA (US)

(21) Appl. No.: 13/269,910

(22) Filed: Oct. 10, 2011

Related U.S. Application Data
(60) Provisional application No. 61/408,337, filed on Oct. 29, 2010.

(51) Int. Cl. G01R 31/26

(52) U.S. Cl. 324/750.16; 324/761.01; 324/756.07

(57) ABSTRACT

The present invention relates to an apparatus for testing of back-contact solar cells. In one embodiment, the apparatus includes a support plate having vacuum holes with suction cups partially within the holes and probe pins within the suction cups. A solar cell is placed into contact with the suction cups and vacuum forces are applied through the suction cups to force contact pads of the solar cell against the probe pins. In another embodiment, the apparatus includes a support plate having probe pin holes with hollow probe pins located therein. Vacuum forces are applied through the hollow probe pins to force contact pads of the solar cell against the probe pins. The support plate in either embodiment may be an end effector of a robot used to pick up the solar cell and hold the front surface of the solar cell adjacent a light source while performing light induced testing.

### CROSS-REFERENCE TO RELATED APPLICATIONS

This application claims benefit of U.S. provisional patent application Ser. No. 61/408,337, filed Oct. 29, 2010, which is herein incorporated by reference.

### BACKGROUND OF THE INVENTION

1. Field of the Invention

The present invention generally relates to testing of back-contact solar cells using an apparatus that locates forces for holding the solar cells within or surrounding electrical testing probes.

2. Description of the Related Art

A conventional solar cell has a p/n junction formed near the front surface, or surface that receives the light, which generates electron/hole pairs as light energy is absorbed in the formed cell. One conventional solar cell design has a first set of electrical contacts on the front side (i.e., light receiving side) of the cell, and a second set of electrical contacts on the back side (i.e., non-light receiving side) of the solar cell. Such conventional solar cells are tested (e.g., light induced voltage (LIV) testing) using electrical probes such as spring loaded pins on each side of the solar cell to contact the first and second sets of electrical contacts of the solar cell. As a result, the force of the pins on the front side of the solar cell is countered by the force of the pins on the back side of the solar cell.

Another solar cell design has both negative-polarity and positive-polarity contacts on the back side of the solar cell. Back-contact solar cells have several advantages compared to conventional solar cells. One advantage is that back-contact cells have a higher conversion efficiency due to reduced or eliminated contact obscuration losses (i.e., sunlight reflected from the contact grid of a conventional solar cell is unavailable to be converted into electricity). Another advantage is that assembly of back-contact cells into electrical circuits is easier, and therefore cheaper, because both conductive contacts are on the same surface. As an example, significant cost savings as compared to conventional solar cell assembly can be achieved with back-contact solar cells by encapsulating the solar cell and the solar cell electrical circuit in a single step. Yet another advantage of a back-contact cell is that the cell has superior aesthetics as compared to conventional solar cells because back-contact solar cells have a more uniform appearance on the front side of the cell (i.e., no front side contacts). Aesthetics are important for certain applications, such as building-integrated photovoltaic systems and photovoltaic sunroofs for automobiles.

Several types of back-contact solar cells exist. Types of back-contact solar cells include metallization wrap around (MWA), metallization wrap through (MWT), emitter wrap through (EWT), and back-junction solar cells. MWA and MWT have metal current collection grids on the front surface. These grids are, respectively, wrapped around the edge or through holes to the back surface in order to make a back-contact cell. A unique feature of EWT cells, in comparison to MWT and MWA cells, is that there is no metal coverage on the front side of the cell, which means that none of the light impinging on the cell is blocked, which results in higher cell efficiencies. The EWT cell wraps the current-collection junction (or “emitter”) from the front surface of the cell to the rear surface of the cell through doped conductive channels in a silicon substrate.

As opposed to conventional solar cells, back-contact solar cells provide a unique challenge to testing, such as LIV testing. Since all of the electrical contacts on a back-contact solar cell are on the back of the cell, contact forces from test probes must be balanced against the forces required to hold the solar cell in place. One conventional method of holding a back-contact solar cell against test probes involves the use of a sheet of glass placed on the front side of the back-contact solar cell, which is used to force the contacts on the back side of the cell against probes while the front side of the cell is exposed to light through the glass. However, in a production setting, glass plates wear and become contaminated, which negatively affects measurements of light induced testing.

Another conventional approach to holding back-contact solar cells during light induced testing involves the use of vacuum chucks. FIG. 1 is a partial, schematic, cross-sectional view of a conventional approach to holding a back-contact solar cell 101 during light induced testing. The back-contact solar cell 101 includes a substrate 102 with conductive back contact pads 103 located on the rear surface 104 of the solar cell 101. A conventional vacuum chuck 100 used for holding the back-contact solar cell 101 includes a plurality of small vacuum holes 110 (e.g., 0.03 inch to 0.05 inch diameter) distributed evenly across the back surface of the solar cell 101 except in probe zones surrounding the back contact pads 103 of the solar cell. Each of the vacuum holes 110 are connected to a vacuum channel 120 within the vacuum chuck 100. The vacuum channel 120 is, in turn, connected to a vacuum pump (not shown) for applying hold-down forces to the solar cell 101. The vacuum chuck 100 further includes a plurality of probe holes 130 formed therethrough. Conductive probe pins 140, such as spring loaded probe pins, are inserted through each probe hole 130 for contacting the contact pads 103 of the back-contact solar cell 101. Thus, vacuum forces generated through the vacuum holes 110 pull the solar cell 101 toward the vacuum chuck 100, overcoming the forces from the probe pins 140, and holding the solar cell 101 in place during testing.

However, several problems exist with this conventional approach. For instance, significant stresses are induced into the thin substrate 102 due to the moment generated by the offset distance between the opposing hold-down and probe pin forces. As an example, in order to have suitably low resistance between the probe pins 140 and the contact pads 103, 15 to 30 grams of force must be provided against each probe pin 140. Any offset between those forces results in a significant moment, and resulting stress, being induced into the brittle, silicon substrate 102, which may result in costly solar cell breakages. In addition, the technological trend is to reduce the amount of silver (i.e., back contact metal) needed on the cell by increasing the number and density of contact pads 103. As the contact pads 103 increase in density and number, the number of probes and resulting forces needed to overcome the probe forces increases, while the available area to pull vacuum against the rear surface 104 of the substrate 102 decreases, which results in greater offset distances and higher stresses being induced into the brittle solar cell 101. Additionally, EWT solar cells provide an added challenge. These solar cells require many thousands of holes, or vias, through the substrate to create the front-to rear electrical contact. With the above-described conventional vacuum handling techniques, the vias become effective air leaks. These leaks make developing sufficient vacuum pressure to overcome the probe pin forces and hold down the back-contact solar cell difficult. Thus, improved methods and apparatus for testing back-contact solar cells are needed.

### SUMMARY OF THE INVENTION

In one embodiment, an apparatus for testing a back-contact solar cell comprises a support plate, one or more test probes disposed at least partially within selected holes disposed in the support plate, and a suction cup disposed within each selected hole. Each selected hole is in fluid communication with a channel for coupling to a vacuum device.

In another embodiment, an apparatus for testing a back-contact solar cell comprises a support plate, and one or more test probes positioned at least partially within selected holes disposed in the support plate. Each test probe has a hole disposed therethrough that is in fluid communication with a channel for coupling to a vacuum device.

In yet another embodiment, a method of testing a back-contact solar cell comprises positioning an end effector of a robot over the back-contact solar cell, applying a vacuum force to secure the back-contact solar cell against the end effector such that predetermined test areas of the back-contact solar cell are drawn into contact with test probes coupled to the end effector, moving the back-contact solar cell and the end effector to a position over a light source using the robot, and measuring one or more electrical characteristics of the back-contact solar cell using the test probes.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial, schematic, cross-sectional view of a conventional approach to holding a back-contact solar cell during light induced testing.

FIG. 2A is partial, schematic, cross-sectional view of an apparatus for holding the back-contact solar cell during light induced testing according to one embodiment.

FIG. 2B is a schematic, isometric view of the apparatus shown in FIG. 2A.

FIG. 3 is a partial, schematic, cross-sectional view of an apparatus for holding the back-contact solar cell during light induced testing according to another embodiment.

FIG. 4 is a partial, schematic, cross-sectional view of an apparatus for holding the back-contact solar cell during light induced testing according to another embodiment.

FIG. 5 is partial, schematic, cross-sectional view of an apparatus for holding the back-contact solar cell during light induced testing according to another embodiment.

FIG. 6 is a schematic, side view of a pick and place robot utilizing the support plate of any of the embodiments shown and described with respect to FIGS. 2A, 2B, 3, 4, and 5 as an end effector.

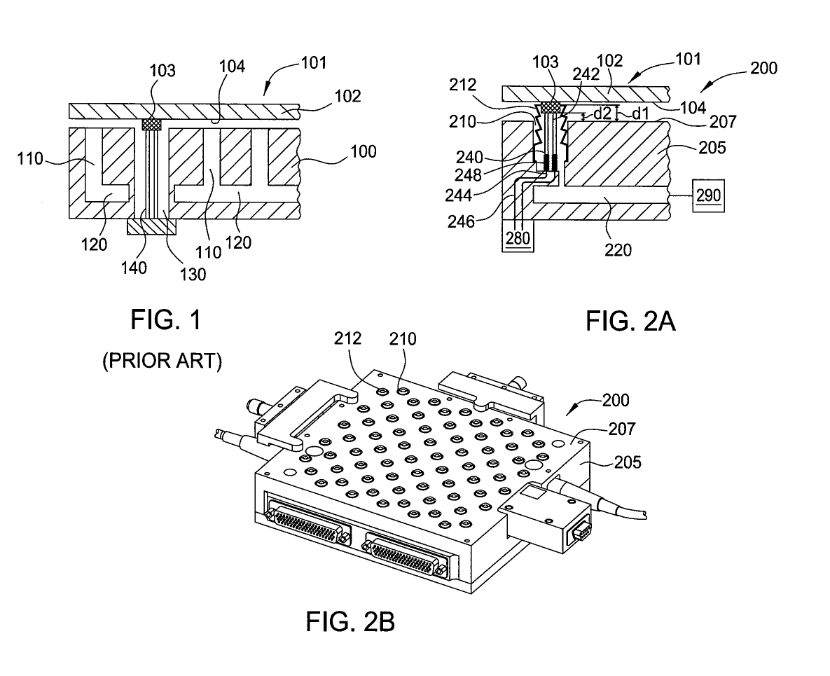

For clarity, identical reference numerals have been used, where applicable, to designate identical elements that are common between figures. It is contemplated that features of one embodiment may be incorporated in other embodiments without further recitation.

### DETAILED DESCRIPTION OF THE INVENTION

The present invention generally relates to testing of back-contact solar cells using an apparatus that locates forces for holding the solar cells within or surrounding electrical testing probes. In one embodiment, the apparatus includes a support plate having vacuum holes with suction cups partially within the holes and probe pins within the suction cups. In this embodiment, a back-contact solar cell is placed into contact with the suction cups and vacuum forces are applied through the suction cups to force contact pads of the back-contact solar cell against the probe pins. In another embodiment, the apparatus includes a support plate having probe pin holes with hollow probe pins located therein. In this embodiment, vacuum forces are applied through the hollow probe pins to force contact pads on the back-contact solar cell against the probe pins. As an example, the support plate in either embodiment may be an end effector of an overhead robot used to pick up the back-contact solar cell and hold the front surface of the solar cell adjacent a light source while performing light induced testing. Thus, each embodiment of the invention provides co-located opposing solar cell holding and probe pin forces to significantly reduce stresses induced into the brittle back-contact solar cell during testing.

FIG. 2A is a partial, schematic, cross-sectional view of an apparatus 200 for holding the back-contact solar cell 101 during light induced testing according to one embodiment. FIG. 2B is a schematic, isometric view of the apparatus 200 shown in FIG. 2A. The apparatus 200 includes a support plate 205 having a plurality of holes 210 formed therein. Each of the holes 210 are in fluid communication with a vacuum channel 220, which is, in turn connected to a vacuum pump 290. Each of the holes 210 has a suction cup 212 positioned and attached within the respect hole 210. Each suction cup 212 is positioned to extend a distance (d1) above a support surface 207 of the support plate 205. The suction cups 212 may include synthetic rubber materials, elastomeric materials, or other polymeric materials as is typical for material handling suction cups. The support plate 205 may be fabricated from a thermally conductive material, such as aluminum, anodized aluminum, or the like.

One or more conductive probe pins 240 are positioned within each of the holes 210 and suction cups 212. In a preferred embodiment, two probe pins 240 are positioned within each hole 210 and suction cup 212 to allow for true Kelvin measurement. A contact end 242 of each probe pin 240 extends above the support surface 207 of the support plate 205 a distance (d2), which is typically less than the distance (d1). The non-contact end 244 of each probe pin 240 may be attached to the support plate 205, and electrical connection between the probe pins 240 and a testing apparatus 280 may be made through wiring 246 extending through a sealed pass-through in the support plate 205. In one example, each probe pin 240 is a spring loaded pin having a spring 248 at the non-contact end 244. The spring 248 allows the contact end 242 of the probe pin 240 to deflect at least the distance (d2) when a force is applied to the probe pin 240. In another example, each probe pin 240 is not spring loaded. In this example, the distance (d2) is controlled to be a minimum distance close to zero to ensure contact between the probe pin 240 and contact pad 103 when vacuum forces are applied.

In operation, the back-contact solar cell 101 is positioned such that the rear surface 104 of the back-contact solar cell 101 is lightly in contact with the suction cups 212 and such that areas surrounding the contact pads 103 of the back-contact solar cell 101 are resting within each suction cup 212 as shown in FIG. 2. Next, a vacuum force is applied through the suction cups 212 using the vacuum pump 290. The vacuum force draws the contact pads 103 into solid electrical contact with the probe pins 240. In the example wherein the probe pins 240 are spring-loaded pins, the vacuum force pulls the rear surface 104 of the back-contact solar cell 101 against the support surface 207 of the support plate 205. In an example wherein the probe pins 240 are not spring-loaded pins, the vacuum pressure is closely controlled to ensure good electrical contact between the probe pins 240 and the contact pads 103, while minimizing stresses induced into the back-contact solar cell 101. In either example, because most of the vacuum force is applied directly on the contact pads 103 and not the surface of the substrate 102, the chance of leakage through the substrate 102 is minimized as compared to the prior art. In addition, since the opposing pin force and vacuum hold-down forces are essentially co-located (i.e., little to no distance between opposing forces), minimal stresses are induced into the brittle substrate 102 as compared to the prior art. Next, light induced testing, such as LIV testing, and measurement of one or more electrical properties of the back-contact solar cell 101 may be performed using a light source 270 (FIG. 6) and the testing apparatus 280.

Examples of the substrate 102 include single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), as well as heterojunction cells, such as GaInP/GaAs/Ge, ZnSe/GaAs/Ge or other similar substrate materials that can be used to convert sunlight to electrical power.

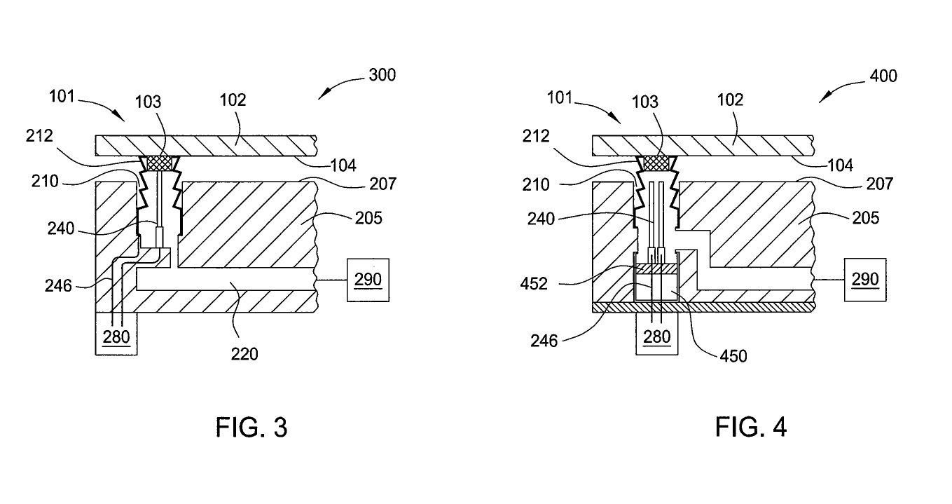

FIG. 3 is partial, schematic, cross-sectional view of an apparatus 300 for holding the back-contact solar cell 101 during light induced testing according to another embodiment. Many of the features of the apparatus 300 are identical to those of the apparatus 200, and thus, will not be described again here. In the embodiment shown in FIG. 3, the suction cup 212 is made of a conductive material, is electrically connected to the testing apparatus 280, and functions as a test probe. In this embodiment, the support plate 205 may be fabricated from a thermally conductive and electrically insulative material, such as anodized aluminum, or insulating inserts may be positioned between the suction cup 212 and the support plate 205. In one example, the suction cup 212 is made of a conductive elastomer, such as elastomeric materials with conductive particles embedded therein (e.g., silver, aluminum, copper). In another example, the suction cup 212 has an over-coating of metallic foil or is made of a metallic foil (i.e., plated bellows). Alternatively, the suction cup 212 may be reduced to raised ridges (not shown) surrounding the hole 210, and the ridges may have conductive contacts (not shown) formed thereon, such as by plating. In conjunction with these embodiments, an optional single probe pin 240 may be provided within the hole 210 and suction cup 212. Thus, true Kelvin measurement may be provided using the single probe pin 240 and the conductive suction cup 212, reducing the number of probe pins 240 needed in the apparatus 300.

FIG. 4 is a partial, schematic, cross-sectional view of an apparatus 400 for holding the back-contact solar cell 101 during light induced testing according to another embodiment. Many of the features of the apparatus 400 are identical to those of the apparatus 200, and thus, will not be described again here. In the embodiment shown in FIG. 4, the suction cup 212 is optional. Additionally, rather than spring-loaded or fixed probe pins 240, the apparatus 400 includes probe pins 240 that are attached to a piston 452 of a cylinder 450 mounted and attached to the support plate 205 as shown in FIG. 4. When the vacuum pump 290 evacuates the air in the hole 210 via the vacuum channel 220, the suction cup 212 deflects, and the rear surface 104 of the solar cell 101 is first drawn against the support surface 207 of the support plate 205. Thus, the suction forces first secure the solar cell 101 to the support plate 205. Then, as the vacuum continues, the piston 452 actuates and is drawn toward the contact pad 103, such that each probe pin 240 is forced to make solid electrical contact with each respective contact pad 103. Thus, by properly sizing the areas of the cylinder 450 and hole 210, the counteracting vacuum and probe forces on the back-contact solar cell 101 can be controlled and induced stresses in the back-contact solar cell 101 can be reduced as compared with the prior art.

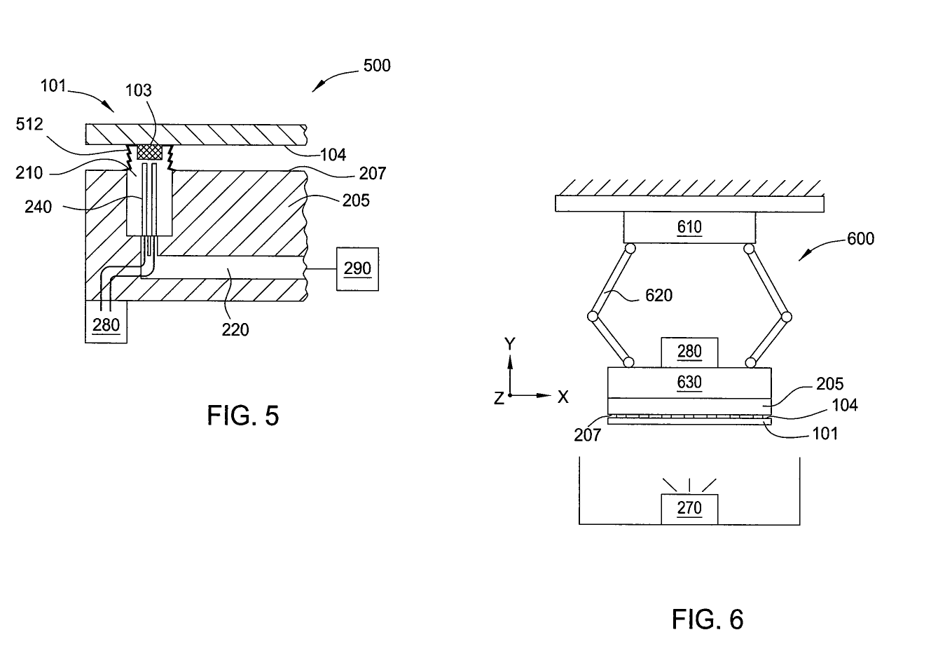

FIG. 5 is a partial, schematic, cross-sectional view of an apparatus 500 for holding the back-contact solar cell 101 during light induced testing according to another embodiment. Many of the features of the apparatus 500 are identical to those of the apparatus 200, and thus, will not be described again here. In the embodiment shown in FIG. 5, the probe pin(s) 240 are hollow, and the hollow region within each probe pin 240 is in fluid communication with the vacuum channel 220. In one example, the hole 210 is in fluid communication with the vacuum channel 220 only through the hollow probe pin(s) 240. In a preferred embodiment, the suction cup 212 is replaced with a thin flexible lip 512 that is attached to the support plate 205 within or surrounding each hole 210. The lip 512 may be made of an elastomeric or other flexible material. When the rear surface 104 of the back-contact solar cell 101 contacts each lip 512 and vacuum is applied through the probe pins 240 using the vacuum pump 290, the region inside the hole 210 is evacuated through the hollow probe pins 240, and an initial seal is formed between the solar cell 101 and the support plate 205. As the vacuum continues, the flexible lip 512 is compressed to allow solid electrical contact between the probe pins 240 and the contact pads 103 of the solar cell 101. Thus, the need for spring-loaded probes is eliminated, and the probe force is controlled based on the vacuum pressure through the hollow probe pins 240.

FIG. 6 is a schematic, side view of a pick and place robot 600 utilizing the support plate 205 of any of the embodiments shown and described with respect to FIGS. 2A, 2B, 3, 4, and 5 as an end effector. The robot 600 generally includes an upper base portion 610, one or more arm devices 620, and an end effector 630. The upper base portion 610 generally includes one or more actuation devices (not shown) for moving the end effector 630 in the X, Y, and Z directions through the arm device(s) 620. The actuation devices may include one or more motors and/or cylinders, for instance. In one example, the upper base portion 610 and the one or more arm devices 620 are similar to a SCARA, six-axis, parallel, or linear type robot that can be adapted to use the end effector 630 to pick, hold, and place back-contact solar cells 101. The base portion 610 may be mounted to an overhead transport system (not show) such as a rail system or the like to move the entire robot 600 from one location to another.

The end effector 630 includes the support plate 205 as shown and described with respect to FIGS. 2A, 2B, 3, 4, and 5. In general, sufficient vacuum force is generated through the support plate 205 by the vacuum pump 290 to secure the back-contact solar cell 101 to the support plate 205 both for movement and testing of the back-contact solar cell 101. In operation, the back-contact solar cell 101 is initially positioned on a supporting surface with the rear surface 104 facing upwardly. The robot 600 lowers the end effector 630 such that the support surface 207 of the support plate 205 is facing and adjacent to the rear surface 104 of the back contact solar cell. Vacuum is then supplied by the vacuum pump 290 to secure the contact pads 103 of the back-contact solar cell 101 in solid electrical contact with the probe pins 240 of the support plate 205. Vacuum is continued such that sufficient vacuum force is supplied to secure the back-contact solar cell 101 against the support surface 207 of the support plate 205. Next, the robot 600 lifts the back-solar cell 101 and holds the solar cell 101 over the light source 270, while electrically monitoring the probe pins 240 using the testing apparatus 280 and measuring at least one electrical characteristic of the back-contact solar cell 101, such as light induced voltage. In addition to light induced voltage, the robot 600 can be used to move the back-contact solar cell 101 to other locations for testing other electrical characteristics, such as dark induced voltage, electroluminescence or the like, all while maintaining vacuum. Thus, damage from repeated solar cell movement and probing is eliminated.

Therefore, the invention includes a number of embodiments that may be used for testing back-contact solar cells. Each of the embodiments minimizes stresses induced into the solar cells through holding and probe forces due to the co-location of the respective forces. In addition, the vacuum forces are applied at the contact pad locations on the back-contact solar cells resulting in lower chances of loosing suction through air leaks through the solar cell. Finally, co-locating vacuum and probe forces also frees up surface area between the back-contact solar cell and the support surface of the apparatus, which is increasing more valuable as the number and density of contact pads of back-contact solar cells increase.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference.

1. An apparatus for testing a back-contact solar cell, comprising:
a support plate;
one or more test probes disposed at least partially within selected holes disposed in the support plate; and
a suction cup disposed within each selected hole, wherein each selected hole is in fluid communication with a channel for coupling to a vacuum device.

2. The apparatus of claim 1, wherein two test probes are disposed at least partially within each of the selected holes.

3. The apparatus of claim 1, wherein each of the one or more test probes is spring-loaded.

4. The apparatus of claim 1, wherein the support plate is an end effector of a robot configured to lift the back-contact solar cell off of a support surface.

5. The apparatus of claim 1, wherein each suction cup is comprised of a conductive material and is configured to function as a test probe.

6. The apparatus of claim 5, wherein a single test probe is disposed at least partially within each of the selected holes.

7. The apparatus of claim 1, wherein each test probe is attached to a cylinder configured to position the test probe relative to the selected hole when vacuum force is applied.

8. The apparatus of claim 1, wherein each of the one or more test probes has a hole disposed therethrough.

9. The apparatus of claim 8, wherein each selected hole in the support plate is in fluid communication with the channel for coupling to the vacuum device.

10. An apparatus for testing a back-contact solar cell, comprising:
a support plate; and
one or more test probes positioned at least partially within selected holes disposed in the support plate, wherein each test probe has a hole disposed therethrough that is in fluid communication with a channel for coupling to a vacuum device.

11. The apparatus of claim 10, wherein the support plate is an end effector of an overhead robot configured to lift the back-contact solar cell off of a support surface.

12. A method of testing a back-contact solar cell, comprising:
positioning an end effector of a robot over the back-contact solar cell;
applying a vacuum force to secure the back-contact solar cell against the end effector such that predetermined test areas of the back-contact solar cell are drawn into contact with test probes coupled to the end effector;
moving the back-contact solar cell and the end effector to a position over a light source using the robot; and
measuring one or more electrical characteristics of the back-contact solar cell using the test probes.

13. The method of claim 12, wherein applying a vacuum force comprises applying vacuum force through selected holes disposed in the end effector.

14. The method of claim 13, wherein one or more of the test probes are disposed at least partially within the selected holes.

15. The method of claim 14, wherein a suction cup is at least partially disposed within each of the selected holes.

16. The method of claim 14, wherein applying the vacuum force causes the test probes to move relative to the selected holes.

17. The method of claim 12, wherein applying a vacuum force comprises applying the vacuum force through apertures disposed in the test probes.

18. The method of claim 12, wherein the one or more test probes are spring-loaded.
